(19) United States
(12) Patent Application Publication
(10) Pub. No.: US 2017/0141272 A1
(43) Pub. Date: May 18, 2017

(54) FRAME FOR SEMICONDUCTOR LIGHT EMITTING DEVICE

(71) Applicant: SEMICON LIGHT CO., LTD., Gyeonggi-do (KR)

(72) Inventors: Eun Hyun PARK, Gyeonggi-do (KR); Soo Kun JEON, Gyeonggi-do (KR); Kyoung Min KIM, Gyeonggi-do (KR); Dong So JUNG, Gyeonggi-do (KR); Kyeong Jea WOO, Gyeonggi-do (KR)

(73) Assignee: SEMICON LIGHT CO., LTD.

(21) Appl. No.: 15/018,402

(22) Filed: Feb. 8, 2016

(30) Foreign Application Priority Data
Nov. 18, 2015 (KR) 10-2015-0161721

(51) Int. Cl. H01L 33/48; H01L 33/60

(52) U.S. Cl. CPC H01L 33/483; H01L 33/60

(57) ABSTRACT

Disclosed is a frame for a semiconductor light emitting device to receive a semiconductor light emitting chip, the frame including: a side wall; and a bottom part, which is connected to the side wall and has at least one hole for receiving a semiconductor light emitting chip.

### CROSS-REFERENCE TO RELATED APPLICATIONS

This application claims the benefit and priority of Korean Patent Application No. 10-2015-0161721, filed Nov. 18, 2015. The entire disclosure of the above application is incorporated herein by reference.

### FIELD

The present disclosure relates generally to a frame for a semiconductor light emitting device, and more particularly to a frame for a semiconductor light emitting device with improved light extraction efficiency.

### BACKGROUND

This section provides background information related to the present disclosure which is not necessarily prior art. Unless specified otherwise, it is appreciated that throughout the description, directional terms, such as upper side/lower side, over/below and so on are defined with respect to the directions in the accompanying drawings.

FIG. 1 is a view showing an exemplary embodiment of a semiconductor light emitting chip in the prior art.

In this semiconductor light emitting chip, there is provided a growth substrate 10 (e.g., a sapphire substrate), and layers including a buffer layer 20, a first semiconductor layer 30 having a first conductivity (e.g., an n-type GaN layer), an active layer 40 adapted to generate light by electron-hole recombination (e.g., INGaN/(In)GaN MQWs) and a second semiconductor layer 50 having a second conductivity different from the first conductivity (e.g., a p-type GaN layer) are deposited over the substrate in the order mentioned. A light-transmitting conductive film 60 for current spreading is then formed on the second semiconductor layer, followed by an electrode 70 serving as a bonding pad formed on the light-transmitting conductive film, and an electrode 80 (e.g., a Cr/Ni/Au stacked metallic pad) serving as a bonding pad is formed on an etch-exposed portion of the first semiconductor layer 30. This particular type of the semiconductor light emitting chip as in FIG. 1 is called a lateral chip. Here, the side of the growth substrate 10 serves as a mounting face during electrical connections to outside.

FIG. 2 is a view showing another exemplary embodiment of a semiconductor light emitting chip disclosed in U.S. Pat. No. 7,262,436. For convenience of description, different reference numerals are used for some parts.

In this semiconductor light emitting chip, there is provided a growth substrate 10, and layers including a first semiconductor layer 30 having a first conductivity, an active layer 40 adapted to generate light by electron-hole recombination and a second semiconductor layer 50 having a second conductivity different from the first conductivity are deposited over the substrate in the order mentioned. Three-layered electrode films 90, 91 and 92 adapted to reflect light towards the growth substrate 10 are then formed on the second semiconductor layer, in which first electrode film 90 can be a reflective Ag film, second electrode film 91 can be a Ni diffusion barrier, and third electrode film 92 can be an Au bonding layer. Further, an electrode 80 serving as a bonding pad is formed on an etch-exposed portion of the first semiconductor layer 30. Here, the side of the electrode film 92 serves as a mounting face during electrical connections to outside. This particular type of the semiconductor light emitting chip as in FIG. 2 is called a flip chip. While the electrode 80 formed on the first semiconductor layer 30 is placed at a lower height level than the electrode films 90, 91 and 92 formed on the second semiconductor layer in the case of the flip chip shown in FIG. 2, it may be formed at the same height level as the electrode films. Here, height levels are given with respect to the growth substrate 10.

FIG. 3 is a view showing one exemplary embodiment of a semiconductor light emitting device 100 in the prior art.

The semiconductor light emitting device 100 is provided with lead frames 110 and 120, a mold 130, and a vertical type light-emitting chip 150 in a cavity 140 which is filled with an encapsulating member 170 containing a wavelength converting material 160. The lower face of the vertical type light-emitting chip 150 is directly electrically connected to the lead frame 110, and the upper face thereof is electrically connected to the lead frame 120. A portion of the light coming out of the vertical type light-emitting chip 150 excites the wavelength converting material 160 such that light of a different color is generated, and these two different lights are mixed to produce white light. For instance, the semiconductor light emitting chip 150 generates blue light, and the wavelength converting material 160 is excited to generate yellow light. Then these blue and yellow lights can be mixed to produce white light. Even though the semiconductor light emitting device shown in FIG. 3 is produced using a vertical type light emitting chip 150, other types of the semiconductor light emitting devices similar to one in FIG. 3 may be produced using the semiconductor light emitting chips illustrated in FIG. 1 and FIG. 2. However, as for the semiconductor light emitting device 100 described in FIG. 3, a bonded state should be established between the semiconductor light emitting chip 150 and the lead frames 110 and 120. Particularly, in case of using the flip chip shown in FIG. 2, it is very likely that light intensity from the flip chip may be lost due to a bonding material (e.g., solder paste) used for bonding the flip chip to the lead frames 110 and 120. Moreover, a properly bonded state may not be established between the semiconductor light emitting chip 150 and the lead frames 110 and 120 because of heat that is generated during the SMT process for bonding the semiconductor light emitting device 100 to an external substrate (e.g., a PCB substrate, a sub-mount, etc.)

In this regard, the present disclosure is directed to provide a frame for a semiconductor light emitting device adapted to receive a semiconductor light emitting chip, thereby allowing electrodes of a semiconductor light emitting chip used in the semiconductor light emitting device to bond directly to an external substrate. More particularly, the present disclosure is directed to provide a frame for a semiconductor light emitting device using a flip chip, in which no bonding between lead frames and the flip chip is required such that no light intensity from the flip chip would be lost due to bonding between the lead frames and the flip chip despite the use of the flip chip.

### SUMMARY

The problems to be solved by the present disclosure will be described in the latter part of the best mode for carrying out the invention.

This section provides a general summary of the disclosure and is not a comprehensive disclosure of its full scope or all of its features.

According to one aspect of the present disclosure, there is provided a frame for a semiconductor light emitting device to receive a semiconductor light emitting chip, the frame including: a side wall; and a bottom part which is connected to the side wall and has at least one hole for receiving a semiconductor light emitting chip.

The advantageous effects of the present disclosure will be described in the latter part of the best mode for carrying out the invention.

### DESCRIPTION OF DRAWINGS

FIG. 1 shows an exemplary embodiment of a semiconductor light emitting chip in the prior art.

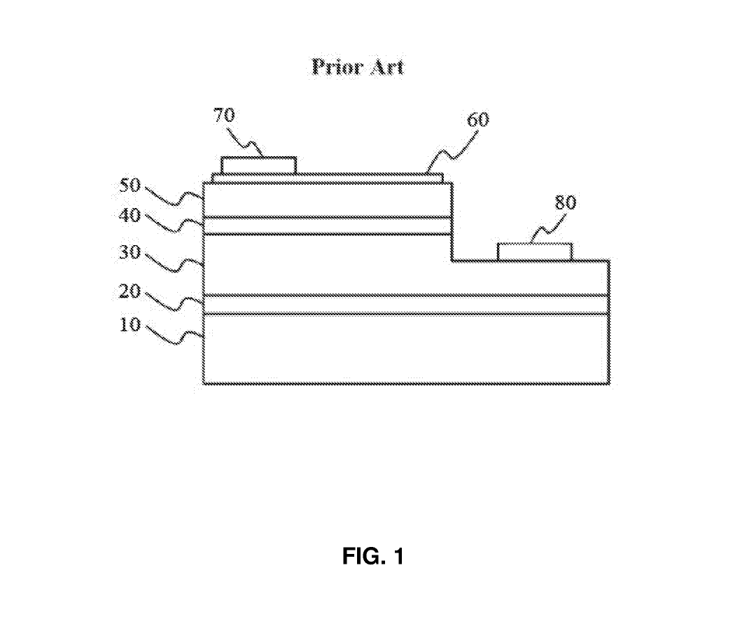

FIG. 2 shows another exemplary embodiment of a semiconductor light emitting chip disclosed in U.S. Pat. No. 7,262,436.

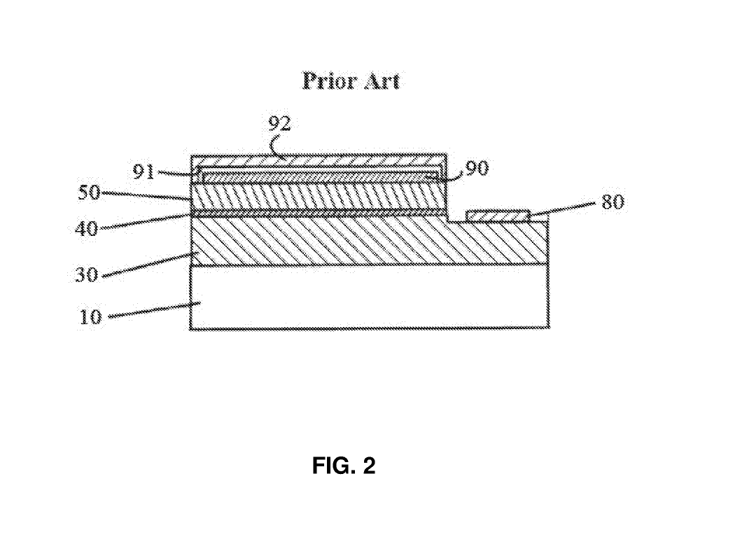

FIG. 3 shows one exemplary embodiment of a semiconductor light emitting device in the prior art.

FIG. 4 shows one exemplary embodiment of a frame for a semiconductor light emitting device according to the present disclosure.

FIG. 5 shows another exemplary embodiment of a frame for a semiconductor light emitting device according to the present disclosure.

FIG. 6 shows yet another exemplary embodiment of a frame for a semiconductor light emitting device according to the present disclosure.

FIG. 7 shows yet another exemplary embodiment of a frame for a semiconductor light emitting device according to the present disclosure.

FIG. 8 shows yet another exemplary embodiment of a frame for a semiconductor light emitting device according to the present disclosure.

FIG. 9 shows various exemplary representations of a reinforcement member in a frame for a semiconductor light emitting device according to the present disclosure.

FIG. 10 shows yet another exemplary embodiment of a frame for a semiconductor light emitting device according to the present disclosure.

FIG. 11 shows yet another exemplary embodiment of a frame for a semiconductor light emitting device according to the present disclosure.

FIG. 12 diagrammatically shows a method for manufacturing a frame for a semiconductor light emitting device according to the present disclosure.

FIG. 13 shows yet other exemplary embodiments of a frame for a semiconductor light emitting device according to the present disclosure.

FIG. 14 shows yet other exemplary embodiments of a frame for a semiconductor light emitting device according to the present disclosure.

FIG. 15 diagrammatically describes principles of improved light extraction when the upper face of the bottom part of a frame for a semiconductor light emitting device according to the present disclosure has at least one of concave and convex portions.

### DETAILED DESCRIPTION

Hereinafter, the present disclosure will now be described in detail with reference to the accompanying drawings. The detailed description herein is presented for purposes of illustration only and not of limitation. The scope of the invention is defined by the appended claims. For example, the steps recited in any of the method or process descriptions may be executed in any order and are not necessarily limited to the order presented. Furthermore, any reference to singular includes plural embodiments, and any reference to more than one component or step may include a singular embodiment or step. Also, the steps recited in any of the method or process descriptions may be executed in any order and are not necessarily limited to the order presented. For convenience in explanation and for better understanding of a frame for a semiconductor light emitting device, the following description will mainly focus on a semiconductor light emitting device where a semiconductor light emitting chip is received in a corresponding frame for a semiconductor light emitting device.

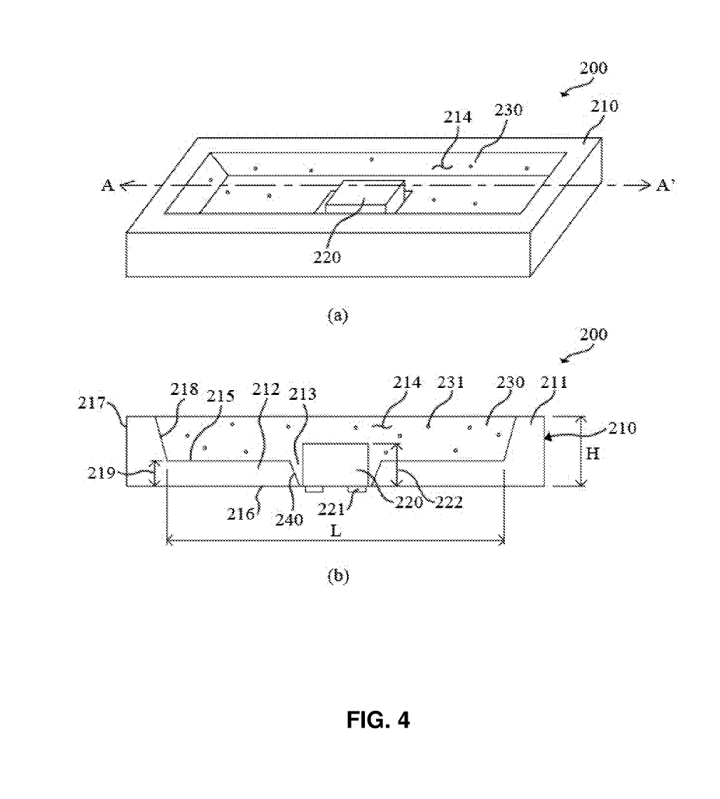

FIG. 4 shows one exemplary embodiment of a frame for a semiconductor light emitting device 200 according to the present disclosure. FIG. 4a is a perspective view, and FIG. 4b is a sectional view taken along line AA′.

The semiconductor light emitting device 200 includes a frame 210 for a semiconductor light emitting device, a semiconductor light emitting chip 220 and an encapsulating member 230.

The frame 210 for a semiconductor light emitting device has a side wall 211 and a bottom part 212. The bottom part 212 has a hole 213 therein. The frame 210 for a semiconductor light emitting device also includes a cavity 214 defined by the side wall 211 and the bottom part 212. The bottom part 212 has an upper face 215 and a lower face 216. The side wall 211 has an outer face 217 and an inner face 218. The side wall 211 may have height H smaller than length L of the bottom part 212. For instance, the height H of the side wall 211 may range from 0.1 mm to 0.6 mm, end points inclusive, and the length L of the bottom part 212 may be 0.5 mm or more. If appropriate, the side wall 211 may be omitted (not shown). It is desirable that the hole 213 is as large as the semiconductor light emitting chip 220 or 1.5 times larger than the semiconductor light emitting chip 220. Moreover, it is desirable that the lateral part 240 of the hole 213 is slanted in order to improve the efficiency of light extraction.

The semiconductor light emitting chip 220 is received into the hole 213. Examples of the semiconductor light emitting chip 220 may include a lateral chip, a vertical chip and a flip chip. The flip chip is preferentially used considering that the electrodes 221 of the semiconductor light emitting chip in the present disclosure are exposed towards the lower face 216 of the bottom part 212 of the frame 210 for a semiconductor light emitting device. It is desirable that the bottom part 212 has a height 219 less than a height 222 of the semiconductor light emitting chip 220. This is so because when the height 219 of the bottom part 212 is greater than the height 222 of the semiconductor light emitting chip 220, the efficiency of light extraction of the semiconductor light emitting device 200 may fall. Despite a possible decrease in the efficiency of light extraction, the bottom part 212 may be configured to have the height 219 greater than the height of the semiconductor light emitting chip 220, taking other factors such as an optical path into consideration. The height 219 of the bottom part 212 and the height 222 of the semiconductor light emitting chip 220 can be measured with respect to the lower face 216 of the bottom part 212. The height 222 of the semiconductor light emitting chip 220 may range from 0.05 mm to 0.5 mm, end points inclusive. The height 219 of the bottom part 212 may range from 0.08 mm to 0.4 mm, end points inclusive.

The encapsulating member 230 is provided at least to the cavity 214 and serves to cover the semiconductor light emitting chip 220 such that the semiconductor light emitting chip 220 received into the hole 213 can be fixed to the frame 210 for a semiconductor light emitting device. The encapsulating member 230 is light transmissive and may be made of either epoxy resins or silicone resins. If necessary, the encapsulating member 230 can have a wavelength converting material 231. Any material (e.g., pigments, dyes or the like) can be used for the wavelength converting material 231, provided that it converts light generated from the active layer of the semiconductor light emitting chip 220 into light having a different wavelength, yet it is desirable to use phosphors (e.g., YAG, (Sr,Ba,Ca)₂SiO₄:Eu or the like) in terms of the efficiency of light conversion). In addition, the wavelength converting material 231 can be selected depending on the color of light from a semiconductor light emitting device, which again is well known to those skilled in the art.

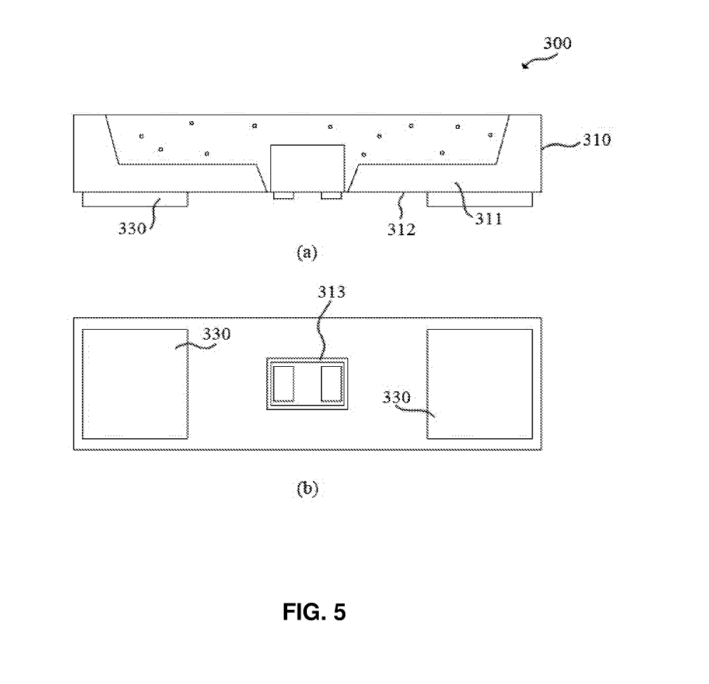

FIG. 5 shows another exemplary embodiment of a frame for a semiconductor light emitting device 300 according to the present disclosure.

The semiconductor light emitting device 300 includes a bonding part 330. Apart from the bonding part 330, the frame 310 for a semiconductor light emitting device has the same configurational features with the frame 210 for a semiconductor light emitting device as shown in FIG. 4. The bonding part 330 is located on the lower face 312 of the bottom part 311 of the frame 310 for a semiconductor light emitting device, while keeping a distance from the hole 313 to be separated from the electrode 321 of the semiconductor light emitting chip 320 that is exposed towards the lower face 312 of the bottom part 311 of the frame 310 for a semiconductor light emitting device. The presence of the bonding part 330 in addition to the electrode 321 contributes to an improved bonding force between the semiconductor light emitting device 300 and an external substrate. The bonding part 330 may be made of a metal. For instance, the bonding part 330 may be made of one of Ag, Cu and Au. The bonding part 330 may also be made of a combination of at least two metals. For instance, it can be made of a combination of Ni and Co, a combination of Cr and Co, or a combination of Ti and Co. The bonding part 330 may be obtained in various combinations of metals and such modification should be easily realized by those skilled in the art. FIG. 5(b), which is a bottom view of FIG. 5(a), clearly shows the layout of the electrodes 321 and the bonding part 330.

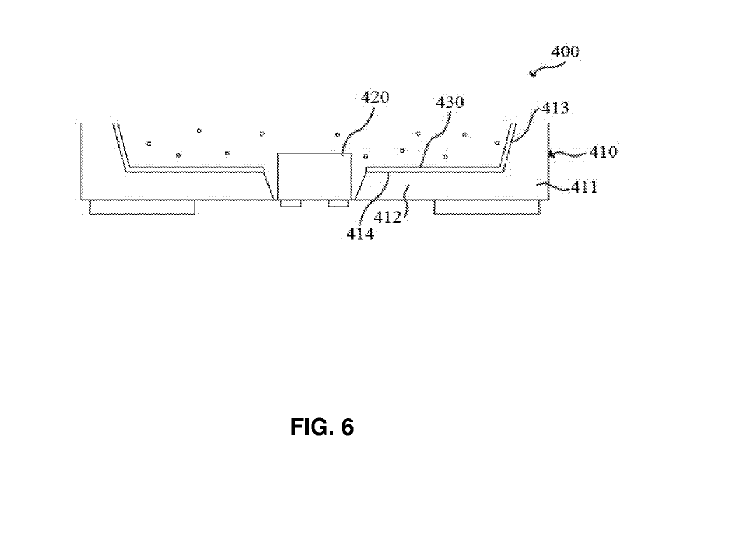

FIG. 6 shows yet another exemplary embodiment of a frame for a semiconductor light emitting device 400 according to the present disclosure.

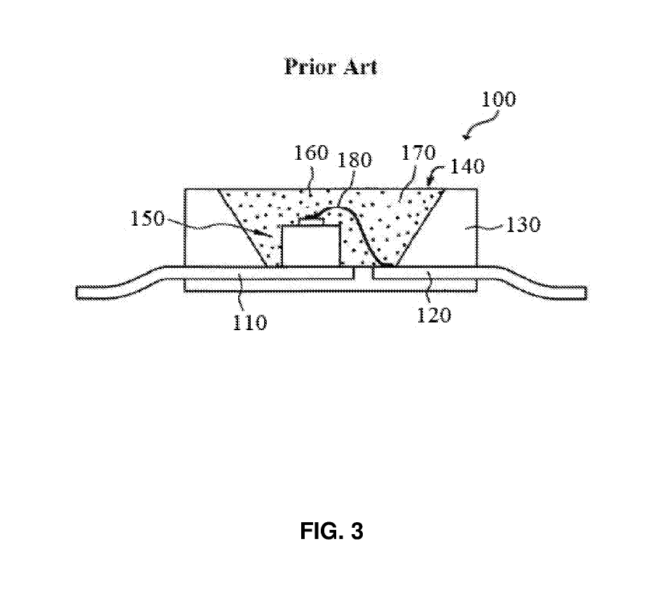

The semiconductor light emitting device 400 includes a reflecting layer 430 formed at at least one of the inner faces 413 of the side wall 411 of the frame 410 for a semiconductor light emitting device and the upper face 414 of the bottom part 412 of the frame 410 for a semiconductor light emitting device. Apart from the reflecting layer 430, the frame 410 for a semiconductor light emitting device has the same configurational features with the frame 310 for a semiconductor light emitting device shown in FIG. 5. The reflecting layer 430 can be formed all over the upper face 414 of the bottom part 412 of the frame 410 for a semiconductor light emitting layer. The reflecting layer 430 may be made of Al, Ag, a DBR (Distributed Bragg Reflector), a high-reflection white substance or the like. Particularly, in the conventional semiconductor light emitting device 100 as shown in FIG. 3, since the semiconductor light emitting chip 150 should be bonded to the lead frames 110 and 120, a reflecting layer made of a metal with high reflectivity could not be formed all over the upper faces of the lead frames 110 and 120, to which the semiconductor light emitting chip 150 is bonded, due to an electrical short. On the contrary, in the present disclosure, there is no lead frame that is bonded to the semiconductor light emitting chip 420, and the semiconductor light emitting chip 420 is not present on the upper face 414 of the bottom part 412. As a result, the reflecting layer 430 made of a metal with high reflectivity can be formed all over the upper face 414 of the bottom part 412. With the reflecting layer 430 made of a metal with high reflectivity formed all over the upper face 414 of the bottom part 412, the efficiency of light extraction of the semiconductor light emitting device 400 can be increased. Although not shown, the reflecting layer 430 may be provided on the lateral faces of a hole.

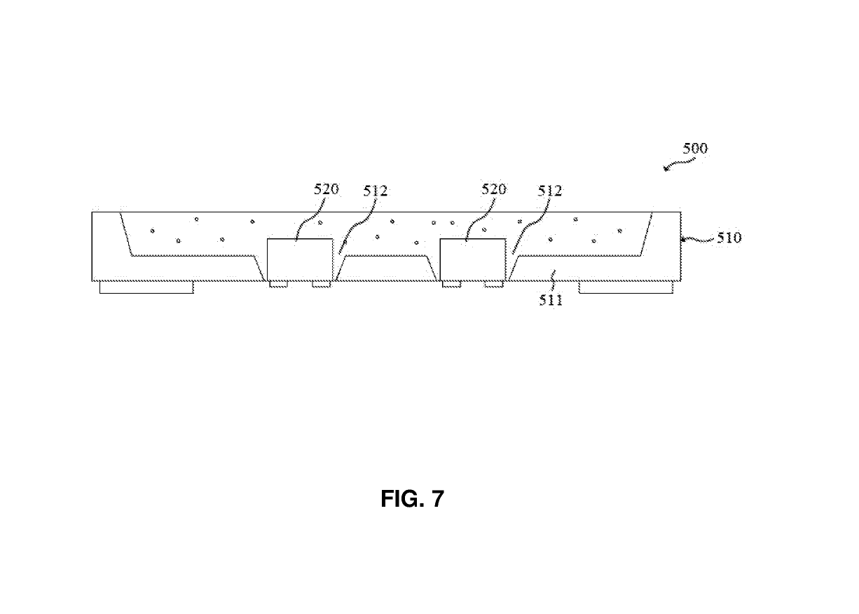

FIG. 7 shows yet another exemplary embodiment of a frame for a semiconductor light emitting device 500 according to the present disclosure.

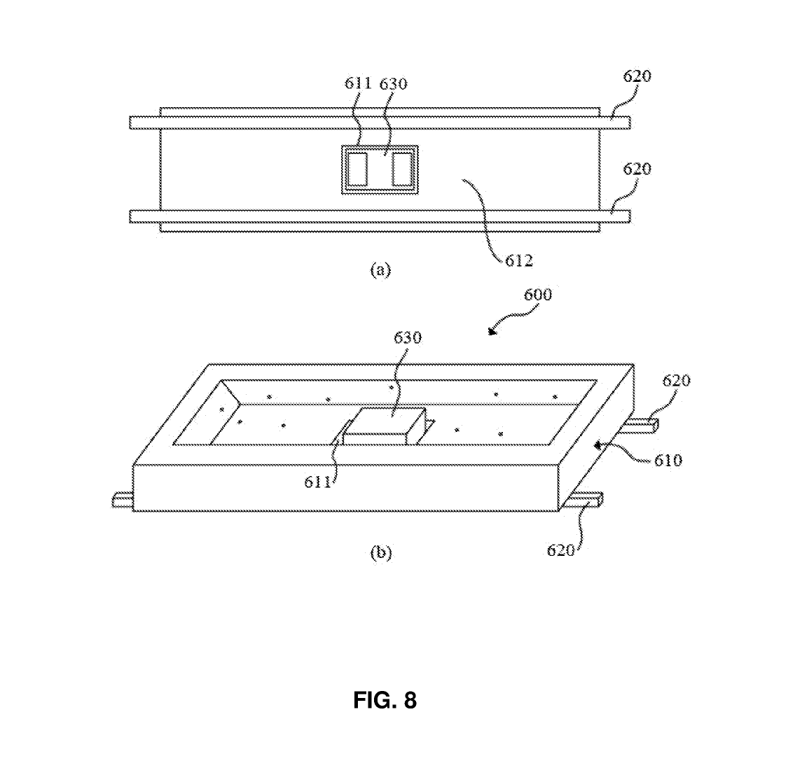

The semiconductor light emitting device 500 has plural holes 512 formed in the bottom part 511 of the frame 510 for a semiconductor light emitting device, and each of the holes 512 receives a semiconductor light emitting chip 520. Apart from these plural holes 512, with each of the holes 512 receiving an individual semiconductor light emitting chip 512, the frame 512 for a semiconductor light emitting device has the same configurational features with the frame 310 for a semiconductor light emitting device shown in FIG. 5. While FIG. 8 illustrates two holes, it is possible to have more than two holes.

FIG. 8 shows yet another exemplary embodiment of a frame for a semiconductor light emitting device 600 according to the present disclosure. FIG. 8(a) is a bottom view, and FIG. 8(b) is a perspective view.

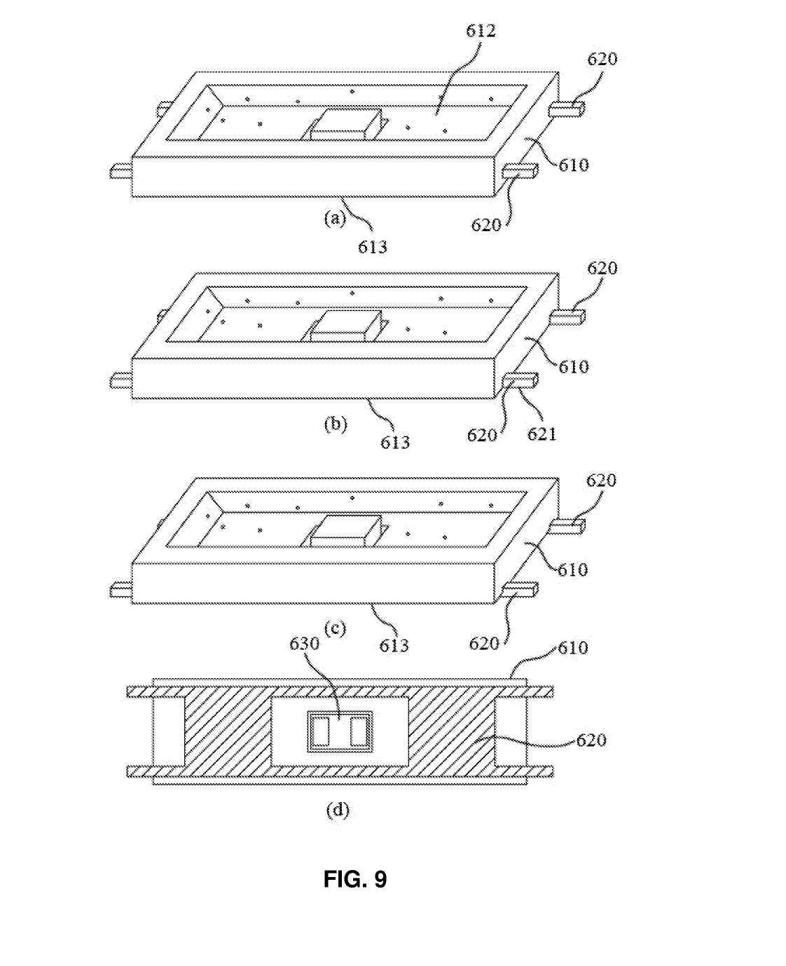

The semiconductor light emitting device 600 has a reinforcement member 620 in the frame 610 for a semiconductor light emitting device. Apart from the reinforcement member 620, the frame 610 for a semiconductor light emitting device has the same configurational features with the frame 210 for a semiconductor light emitting device shown in FIG. 4. The semiconductor light emitting device 600 may have plural reinforcement members 620. When two reinforcement members 620 are provided as shown in FIG. 8, a hole 611 and a semiconductor light emitting chip 630 received into the hole 611 may be positioned between the reinforcement members 620. In other words, it is desirable that the reinforcement members 620 and the hole 611 are arranged in a non-overlapped fashion. The reinforcement members 620 can resolve issues like bending of the frame 610 for a semiconductor light emitting device or breaking of the frame 610 for a semiconductor light emitting device that results from the bending. The reinforcement members 620 are preferably made of a metal. The lead frame described in FIG. 3 may also be used as the reinforcement member 620. Moreover, the reinforcement members 620 positioned as shown in FIG. 8(a) and those reinforcement members 620 positioned as shown in FIG. 9(b) and FIG. 9(c) may function as a bonding part described in FIG. 5.

FIG. 9 shows various exemplary representations of a reinforcement member in a frame for a semiconductor light emitting device according to the present disclosure. FIG. 9(a) through FIG. 9(c) are perspective views, and FIG. 9(d) is a bottom view.

FIG. 9(a) through FIG. 9(c) are various exemplary representations of the reinforcement member 620 placed in different locations, such as, between the upper face 612 and the lower face 313 of the bottom part of the frame 610 for a semiconductor light emitting device. In particular, FIG. 9(a) shows that the reinforcement members 620 are completely inserted into the frame 610 for a semiconductor light emitting device. FIG. 9(b) shows that the reinforcement members 620 are arranged in a way that the lower faces 621 of the reinforcement members 620 are on the same level with the lower face 613 of the bottom part of the frame 610 for a semiconductor light emitting device. FIG. 9(c) shows that the reinforcement members 620 are arranged in a way that part of each reinforcement member 620 is protruded from the lower face 613 of the bottom part of the frame 610 for a semiconductor light emitting device. FIG. 9(d) shows that the reinforcement members 620 are formed along the length and width of the frame 610 for a semiconductor light emitting device, which is different from the reinforcement members 620 formed only along the length of the frame 610 for a semiconductor light emitting device. That is to say, it is desirable to form the reinforcement members 620 as wide as possible without overlapping with the hole in the frame 610 for a semiconductor light emitting device, in order to resolve issues like bending of the frame 610 for a semiconductor light emitting device or breaking of the frame 610 for a semiconductor light emitting device that results from the bending.

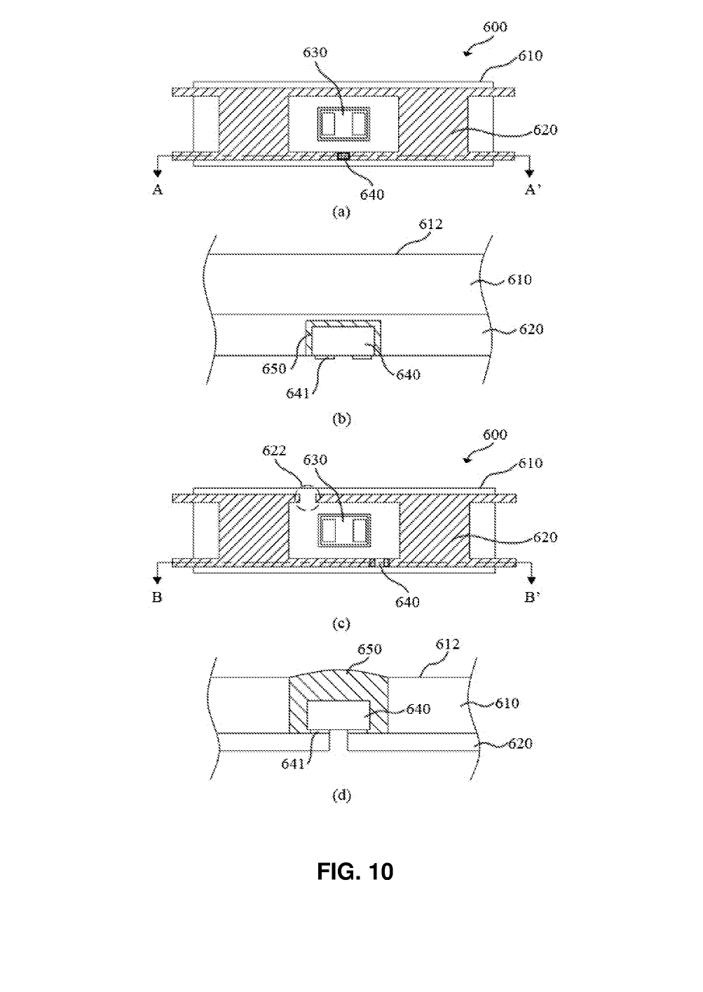

FIG. 10 shows yet another exemplary embodiment of a frame for a semiconductor light emitting device 600 according to the present disclosure. FIG. 10(a) and FIG. 10(c) are bottom views, FIG. 10(b) is a sectional view taken along line AA′, and FIG. 10(d) is a sectional view taken along line BB′.

The semiconductor light emitting device 600 has reinforcement members 620, and

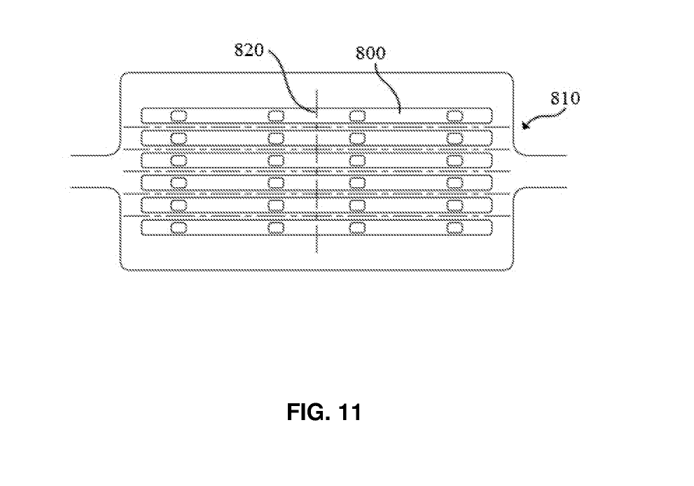

The semiconductor light emitting device 700 has a reinforcement member 720, and the reinforcement member 720 contains therein a protecting element 740 (e.g., a Zener diode or a PN diode) for protecting the semiconductor light emitting chip 730 from static electricity or a reverse current, as shown in FIG. 11(a) and FIG. 11(b). The protecting element 640 is all covered with a white silicone resin 650 for example, except for electrodes 641 thereof. To clarify the locational relationship of the protecting element 640, the upper face 612 of the bottom part of the frame 610 for a semiconductor light emitting device is also depicted. However, such a small protecting element 640 can make it difficult to mount the protecting element 640 directly onto the electrodes of an external substrate. To overcome this, the protecting element 640 may be inserted into the frame 610 for a semiconductor light emitting device as illustrated in FIG. 10(c) and FIG. 10(d). As such, the electrodes 641 of the protecting element 640 are placed on the reinforcement member 620 in a shorted state and electrically connected with the reinforcement member 620. The protecting element 640 is covered with a white silicone resin 650. The reinforcement members 620, together with the semiconductor light emitting chip 630, are connected to the electrodes of an external substrate. To avoid a short, the reinforcement member as shown in FIG. 10(c) is shorted 622. Those protecting elements 640 shown in FIG. 10(a) and FIG. 10(c) are electrically connected in anti-parallel with the semiconductor light emitting chip 630 through the electrodes of an external substrate. In particular, FIG. 10(a) shows that the protecting element 640 is directly electrically connected with an external substrate, while FIG. 10(c) shows that the protecting element 640 is electrically connected with an external substrate via the reinforcement member 620. Those skilled in the art can easily conceive such an electrode array of an external substrate that allows electrical anti-parallel connection between the semiconductor light emitting chip 630 and the protecting element 640 as illustrated in FIG. 10(a) and FIG. 10(c).

FIG. 11 shows exemplary representations of a frame for a semiconductor light emitting device 700 according to the present disclosure. The semiconductor light emitting device 700 has plural holes 712 formed in the bottom part 711 of the frame 710 for a semiconductor light emitting device, and each of the holes 712 receives a semiconductor light emitting chip 720. Also, in the frame 710 for a semiconductor light emitting device, barriers 713 are arranged between the holes 712. With these barriers 713, plural cavities 714 are formed in correspondence to the plural holes 712. Different wavelength converting materials 731 and 732 may be used in the plural cavities 714. For instance, as shown in FIG. 11, three semiconductor light emitting chips 720 emitting blue light are placed in their respective holes 712. An encapsulating member 730 free of a wavelength converting material can be used in one cavity 714, an encapsulating member 730 containing a wavelength converting material 731 that is excited by blue light and emits green light can be used in another cavity 714, and an encapsulating member 730 containing a wavelength converting material 732 that is excited by blue light and emits red light can be used in the other cavity 714. Under the presence of the barriers 713, lights from the plural cavities 714 are not interfered with each other. More specifically, the wavelength converting materials 731 and 732 contained in the respective cavities 714 may not be affected by those lights coming out of the plural cavities 714. With this configuration, the resulting semiconductor light emitting device can generate diverse colors with high purity and white lights with different color temperatures, and have a high color render index. The other configurational features not described in reference to FIG. 11 are the same as those of the frame 510 for a semiconductor light emitting device shown in FIG. 7.

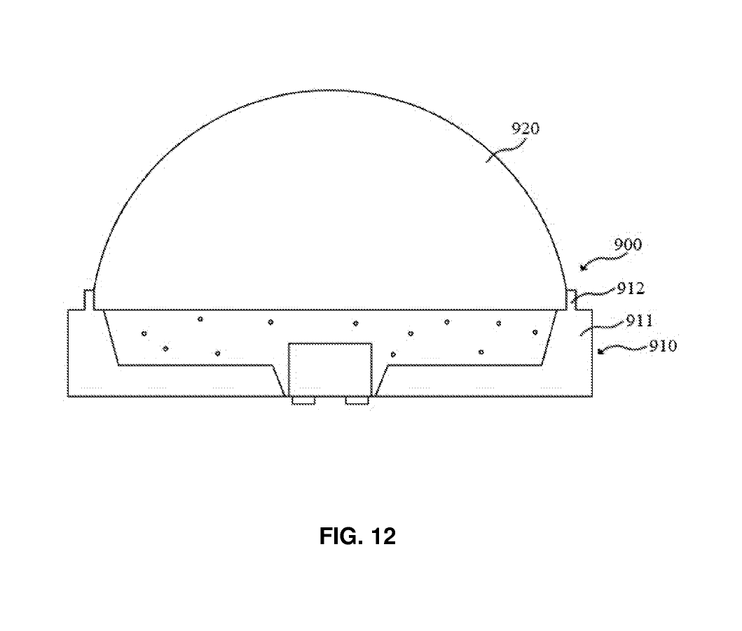

FIG. 12 diagrammatically shows a method for manufacturing a frame 800 for a semiconductor light emitting device according to the present disclosure.

The frame 800 for a semiconductor light emitting device can be obtained by injection molding. Once a substrate 810 including plural frames 800 for a semiconductor light emitting device as shown in FIG. 12 is prepared by injection molding, the substrate is cut along a cutting line 820 and each can be used as the frame 800 for a semiconductor light emitting device.

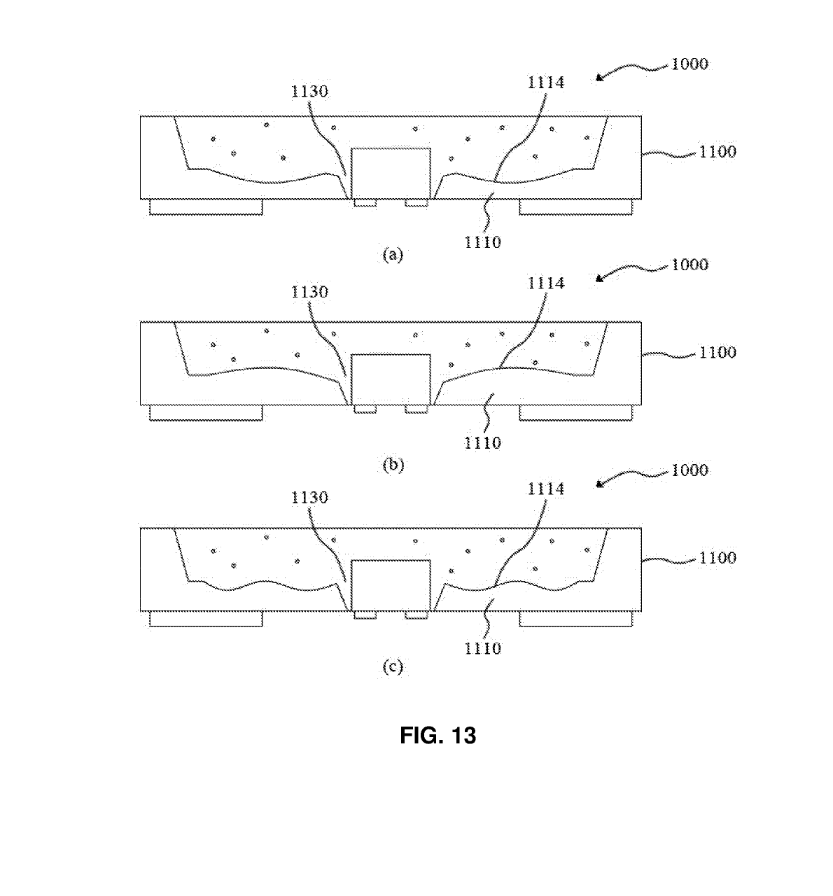

FIG. 13 shows yet other exemplary embodiments of a frame for a semiconductor light emitting device 900 according to the present disclosure.

The semiconductor light emitting device 900 includes a frame 910 for a semiconductor light emitting device with a side wall 911 having a protruded portion 912. and a lens 920 formed on the encapsulating member and between the protruded portions 912. The other configurational features not described in reference to FIG. 13 are the same as those of the frame 210 for a semiconductor light emitting device shown in FIG. 4. The protruded portions 912 serve as boundary projections to prevent the lens 920 being formed from going over the protruded portions 912.

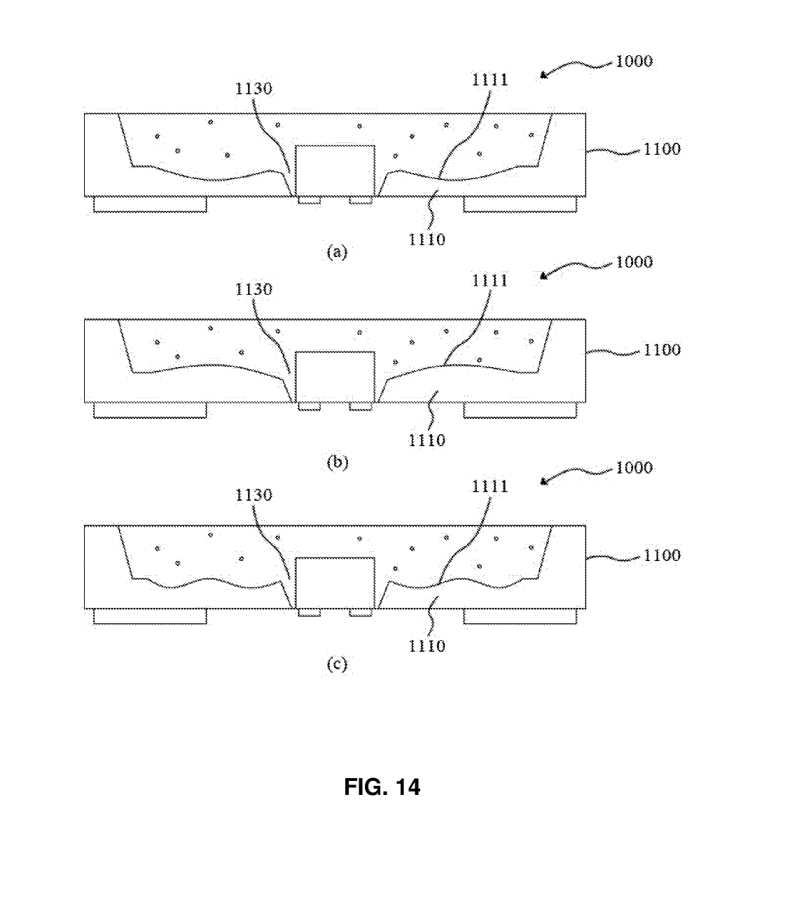

FIG. 14 shows yet other exemplary embodiments of a frame for a semiconductor light emitting device 1000 according to the present disclosure.

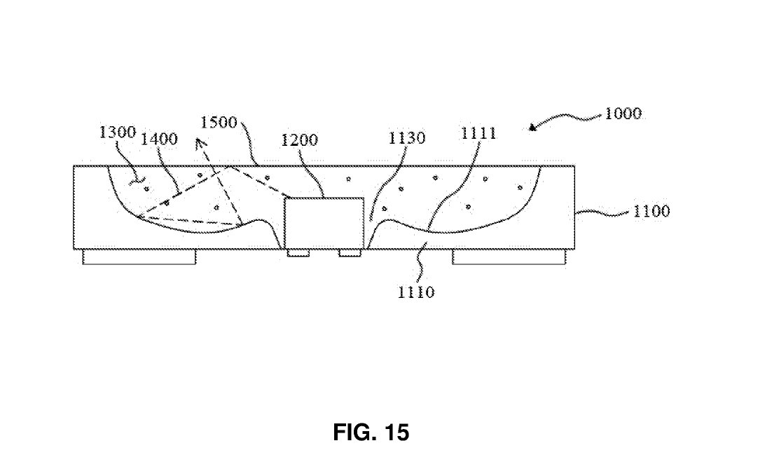

The semiconductor light emitting device 1000 includes a frame 1100 for a semiconductor light emitting device, with the frame 1100 having at least one of concave and convex portions on the upper face 1111 of the bottom part 1110 thereof. In particular, the upper face 1111 of the bottom part 1110 of the frame 1100 for a semiconductor light emitting device has a concave portion as shown in FIG. 14(a), or a convex portion as shown in FIG. 14(b), or concave and convex portions consecutively as shown in FIG. 14(c). When the upper face of the bottom part has at least one of concave and convex portions, the semiconductor light emitting device 1000 may have an increased light extraction efficiency, and the reason for such an increase in the efficiency of light extraction will be explained later in reference to FIG. 15. The other configurational features not described in reference to FIG. 14 are the same as those of the frame 310 for a semiconductor light emitting device shown in FIG. 5.

FIG. 15 diagrammatically describes principles of improved light extraction when the upper face of the bottom part of the frame for a semiconductor light emitting device 1000 according to the present disclosure has at least one of concave and convex portions.

Light 1400 from a semiconductor light emitting chip 1200 in the semiconductor light emitting device 1000 is reflected from a boundary 1500 between an encapsulating member 1300 and outside. This reflected light 1400 can be reflected by a concave portion of the upper face 1111 of the bottom part 1110 of the frame 1100 for a semiconductor light emitting device in a dotted line and then escape from the semiconductor light emitting device 1000. In other words, light that might have been captured inside the semiconductor light emitting device 1000 when the upper face 1111 of the bottom part 1110 is flat can still escape from the semiconductor light emitting device 1000 as the upper face 1111 of the bottom part 1110 has at least one of convex and concave portions, and this will bring about an increased efficiency of light extraction. It is more desirable to have a concave portion on the upper face 1111 of the bottom part 1110 in terms of higher light extraction efficiency.

The following describes diverse exemplary embodiments of the present disclosure.

(1) A frame for a semiconductor light emitting device to receive a semiconductor light emitting chip, the frame comprising: a side wall; and a bottom part, which is connected to the side wall and has at least one hole for receiving a semiconductor light emitting chip.

(2) A frame for a semiconductor light emitting device, wherein a reflecting layer is formed at at least one of inner faces of the side wall of a frame and an upper face of the bottom part of a frame.

(3) A frame for a semiconductor light emitting device, wherein a reflecting layer is formed all over the upper face of the bottom part of a frame.

(4) A frame for a semiconductor light emitting device, wherein a reflecting layer is a metallic layer.

(5) A frame for a semiconductor light emitting device to receive a semiconductor light emitting chip, the frame comprising: a side wall; a bottom part, which is connected to the side wall and has at least one hole for receiving a semiconductor light emitting chip; and a bonding part provided at the lower face of the bottom part, the bonding part being located a distance away from the hole in the bottom part.

(6) A frame for a semiconductor light emitting device, wherein a bonding part is made of a metal.

(7) A frame for a semiconductor light emitting device, wherein a side wall have a height greater than length of a bottom part.

(8) A frame for a semiconductor light emitting device, wherein plural holes are formed, and barriers are arranged between the holes.

(9) A frame for a semiconductor light emitting device, wherein a hole has slanted lateral faces.

(10) A frame for a semiconductor light emitting device, wherein a side wall has a protruded portion.

(11) A frame for a semiconductor light emitting device to receive a semiconductor light emitting chip, the frame comprising: a side wall; a bottom part, which is connected to the side wall and has at least one hole for receiving a semiconductor light emitting chip; and at least one reinforcement member provided at the bottom part, which is arranged in a non-overlapping fashion with the hole in the bottom part.

(12) A frame for a semiconductor light emitting device, wherein a reinforcement member is located between the upper face and the lower face of the bottom part of a frame.

(13) A frame for a semiconductor light emitting device, wherein a reinforcement member is located at the lower face of the bottom part of a frame.

(14) A frame for a semiconductor light emitting device, wherein a reinforcement member comprises a protecting element.

(15) A frame for a semiconductor light emitting device, wherein a bottom part comprises a protecting element, and electrodes of the protecting element are placed on the reinforcement member in a shorted state.

(16) A frame for a semiconductor light emitting device, wherein the upper face of the bottom part of a frame has at least one of concave and convex portions.

According to the present disclosure, a frame for a semiconductor light emitting device can be obtained, in which the electrodes of a semiconductor light emitting chip being received are bonded directly to an external substrate.

Moreover, according to the present disclosure, a frame for a semiconductor light emitting device can be obtained, which does not require bonding between lead frames and a flip chip such that no light intensity from the flip chip may be lost due to the bonding between the lead frames and the flip chip.

### DESCRIPTION OF REFERENCE NUMERALS

Frame for a semiconductor light emitting device: 210, 310, 410, 510, 610, 710, 800, 910, 1100

Semiconductor light emitting chip: 150, 220, 320, 420, 520, 630, 720, 1200

Reinforcement member: 620

What is claimed is:

1. A frame for a semiconductor light emitting device to receive a semiconductor light emitting chip, the frame comprising:
A side wall; and
a bottom part, which is connected to the side wall and has at least one hole for receiving a semiconductor light emitting chip.

2. The frame for a semiconductor light emitting device of claim 1, wherein a reflecting layer is formed at at least one of inner faces of the side wall and an upper face of the bottom part

3. The frame for a semiconductor light emitting device of claim 2, wherein the reflecting layer is formed all over the upper face of the bottom part.

4. The frame for a semiconductor light emitting device of claim 3, wherein the reflecting layer is a metallic layer.

5. The frame for a semiconductor light emitting device of claim 1, comprising: a bonding part provided at the lower face of the bottom part, the bonding part being located a distance away from the hole in the bottom part.

6. The frame for a semiconductor light emitting device of claim 5, wherein the bonding part is made of a metal.

7. The frame for a semiconductor light emitting device of claim 1, wherein the side wall have a height greater than length of the bottom part.

8. The frame for a semiconductor light emitting device of claim 1, wherein plural holes are formed, and barriers are arranged between the holes.

9. The frame for a semiconductor light emitting device of claim 1, wherein the hole has slanted lateral faces.

10. The frame for a semiconductor light emitting device of claim 1, wherein the side wall has a protruded portion.

11. The frame for a semiconductor light emitting device of claim 1, comprising: at least one reinforcement member provided at the bottom part, which is arranged in a non-overlapping fashion with the hole in the bottom part.

12. The frame for a semiconductor light emitting device of claim 11, wherein the reinforcement member is located between the upper face and the lower face of the bottom part.

13. The frame for a semiconductor light emitting device of claim 11, wherein the reinforcement member is located at the lower face of the bottom part.

14. The frame for a semiconductor light emitting device of claim 11, wherein the reinforcement member comprises a protecting element.

15. The frame for a semiconductor light emitting device of claim 11, wherein the bottom part comprises a protecting element, and electrodes of the protecting element are placed on the reinforcement member in a shorted state.

16. The frame for a semiconductor light emitting device of claim 1, wherein the upper face of the bottom part has at least one of concave and convex portions.
